(19) United States
(12) Patent Application Publication
(10) Pub. No.: US 2011/0084344 A1
(43) Pub. Date: Apr. 14, 2011

(54) MEMS DEVICE WITH A COMPOSITE BACK PLATE ELECTRODE AND METHOD OF MAKING THE SAME

(76) Inventors: Chien-Hsin Huang, Taichung City (TW); Bang-Chiang Lan, Taipei City (TW); Ming-I Wang, Taipei County (TW); Hui-Min Wu, Hsinchu County (TW); Tzung-I Su, Yun-Lin County (TW); Chao-An Su, Kaohsiung County (TW); Tzung-Han Tan, Taipei City (TW); Min Chen, Taipei County (TW); Meng-Jia Lin, Changhua County (TW)

(21) Appl. No.: 12/579,395

(22) Filed: Oct. 14, 2009

(51) Int. Cl. H01L 29/84; H01L 21/30

(52) U.S. Cl. 257/415; 438/53; 257/E21.211; 257/E29.324

(57) ABSTRACT

A method of fabricating MEMS device includes: providing a substrate with a first surface and a second surface. The substrate includes at least one logic region and at least one MEMS region. The logic region includes at least one logic device positioned on the first surface of the substrate. Then, an interlayer material is formed on the first surface of the substrate within the MEMS region. Finally, the second surface of the substrate within the MEMS region is patterned. After the pattern process, a vent pattern is formed in the second surface of the substrate within the MEMS region. The interlayer material does not react with halogen radicals. Therefore, during the formation of the vent pattern, the substrate is protected by the interlayer material and the substrate can be prevented from forming any undercut.

### BACKGROUND OF THE INVENTION

1. Field of the Invention

The present invention relates to a MEMS device and the fabricating method of the MEMS device, and more particularly, to a MEMS microphone and a fabricating method of the MEMS microphone.

2. Description of the Prior Art

The demand for MEMS devices such as MEMS microphones and MEMS speakers is increasing. Many cell phones are equipped with MEMS speakers for broadcasting ring tones and MEMS microphones for video recording. These MEMS microphones and MEMS speakers can also be applied to other portable digital devices with flash memories.

MEMS microphones work on a principle of variable capacitance and voltage by the movement of an electrically charged diaphragm relative to a backplate electrode in response to sound pressure. The backplate electrode has a vent pattern with a plurality of trenches, wherein the vent pattern is usually formed by an etching process. However, an undercut is formed on the silicon substrate when the etchant for the vent pattern contacts the silicon oxide layer or other isolating layers. The undercut will damage the integrity of the MEMS microphone, thereby causing the performance of the MEMS microphone to deteriorate.

Therefore, there is a considerable need to find a new method to prevent the undercut when fabricating a MEMS microphone.

### SUMMARY OF THE INVENTION

It is one objective of the present invention to provide a fabricating method to prevent undercut when forming a vent pattern in a MEMS microphone. The method of the present invention is compatible with the method for forming a semiconductor device.

According to a preferred embodiment of the present invention, a method of fabricating a MEMS device comprises: providing a substrate with a first surface and a second surface, the substrate comprising a logic region and at least one MEMS region, the logic region comprising at least one logic device positioned on the first surface of the substrate. Then, an interlayer material is formed on the first surface of the substrate within the MEMS region. Finally, the second surface of the substrate within the MEMS region is patterned to form a vent pattern in the second surface of the substrate within the MEMS region.

According to another preferred embodiment of the present invention, a MEMS device with composite backplate electrode comprises: a composite backplate electrode, a diaphragm, a chamber disposed between the backplate electrode and the diaphragm and a recess disposed aside the diaphragm and opposite the chamber. The composite backplate electrode includes a first material, a second material partly on the first material, wherein the second material does not react with any halogen radical, and a vent pattern disposed within the first material and the second material.

The feature of the present invention is that the aforesaid interlayer material does not react with halogen radicals. Therefore, the interlayer material disposed on the substrate can serves as a protective layer of the substrate. In this way, the undercut formed during the traditional fabrication of the vent pattern can be prevented.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 11 are diagrams schematically depicting the method of fabricating a MEMS microphone according to a preferred embodiment of the present invention.

FIG. 11 to FIG. 13 are diagrams schematically depicting the method of fabricating a MEMS microphone according to another preferred embodiment of the present invention.

### DETAILED DESCRIPTION

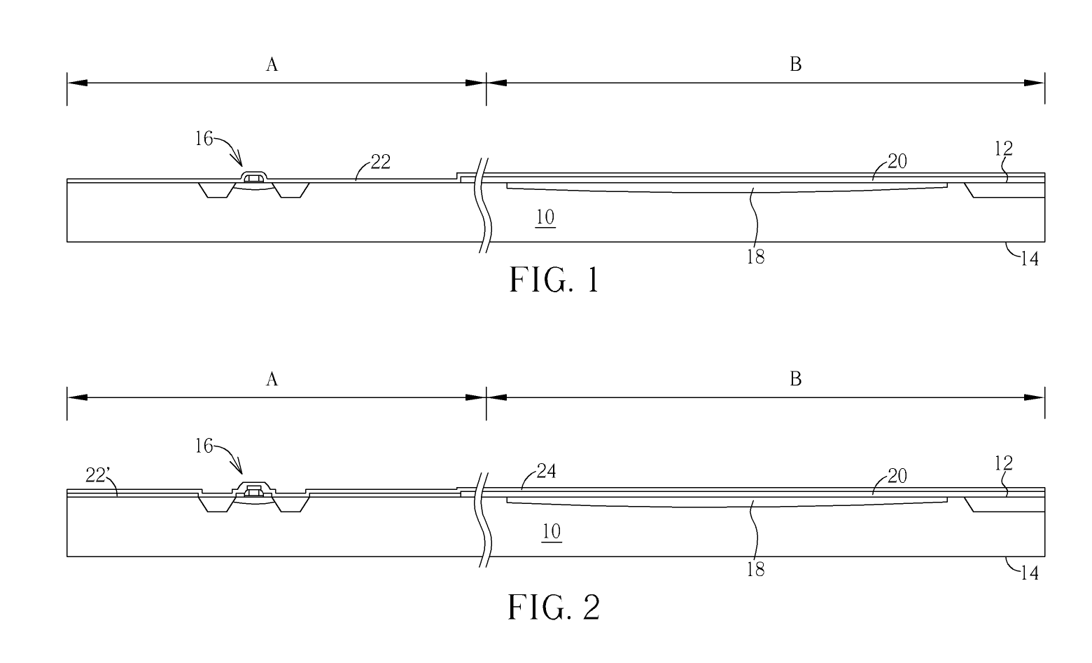

FIG. 1 to FIG. 13 are diagrams schematically depicting the method of fabricating a MEMS microphone. As shown in FIG. 1, first, a substrate 10 comprising a first surface 12 such as an active area and a second surface 14 such as a backside is provided. The substrate 10 includes at least one logic region A and at least one MEMS region B. A logic device 16 is disposed on the first surface 12 of the substrate 10 within the logic region A. The MEMS region B of the substrate 10 further includes a doped region 18 such as a P-type doped region or a N-type doped region. The logic device 16 may be a transistor such as a MOS transistor or a CMOS transistor. The substrate 10 may be a silicon on insulator (SOI) substrate, a single crystalline substrate or a multiple crystalline substrate. Then, a salicide block layer 20 such as silicon oxide, silicon or other dielectric materials is formed entirely on the first surface 12 of the substrate 10 within the MEMS region B and the logic region A. After that, the salicide block layer 20 within the logic region A is removed. Later, a metal layer 22 such as Ni, Co, Pt, Pd, Mo, Ti, the combination thereof or the alloy thereof is formed on the first surface 12 of the substrate 10 within the logic region A and the remanding salicide block layer 20 within the MEMS region B. After that, a salicide process is preformed to the metal layer 22 to form a silicide layer 22′ on the signal input or output such as the source, the drain, the gate of the logic device 16 and the exposed substrate 10.

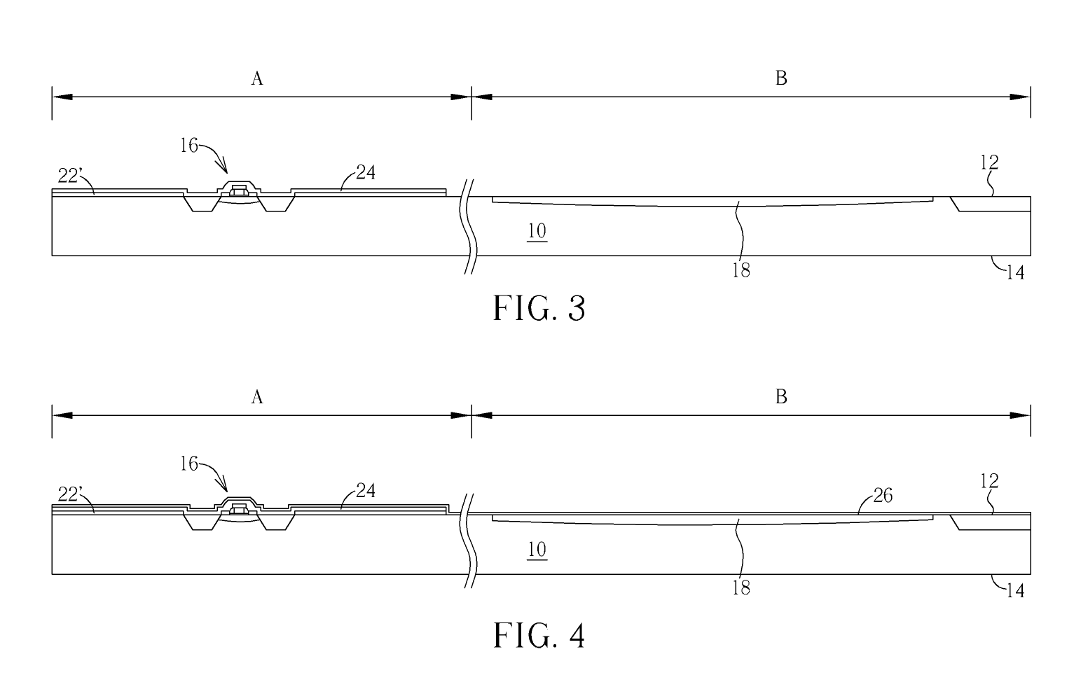

As shown in FIG. 2, the unreacted metal layer 22 is removed. Later, a sacrificial layer 24 such as silicon oxide, silicon nitride or other dielectric materials is formed entirely on the logic region A, the MEMS region B of the substrate 10 and the logic device 16. The sacrificial layer 24 is utilized as an etching stop layer in the following process. After that, as shown in FIG. 3, the sacrificial layers 24 within the MEMS region B and the salicide block layer 20 are removed together by a lithographic process, and the first surface 12 within the MEMS region B is exposed.

As shown in FIG. 4, an interlayer material 26 is formed entirely on the first surface 12 of the substrate 10 within the MEMS region B, and the sacrificial layer 24 within the logic region A. The interlayer material 26 can select from the group consisting of Co, Ni, Pt, Pd, Mo, Al, or other metal materials which do not react with halogen radicals. After the interlayer material 26 such as Co, Ni, Pt, Pd, Mo or Al is formed; a salicide process can be performed optionally to the interlayer material 26. Then, the interlayer material 26 becomes CoSi, NiSiPt, PdSi, MoSi, AlSi or other silicides. In other words, the interlayer material 26 can be metal materials which do not react with halogen radicals such as Co, Ni, Pt, Pd, Mo, or Al, and the interlayer material 26 can also be a silicide which do not react with halogen radicals such as CoSi, NiSiPt, PdSi, MoSi, or AlSi. If the interlayer material 26. is a silicide, the interlayer material 26 will not cover on the shallow trench isolation in MEMS region B. FIG. 4 is exemplified as the interlayer material 26 is Co, Ni, Pt, Pd, Mo, or Al.

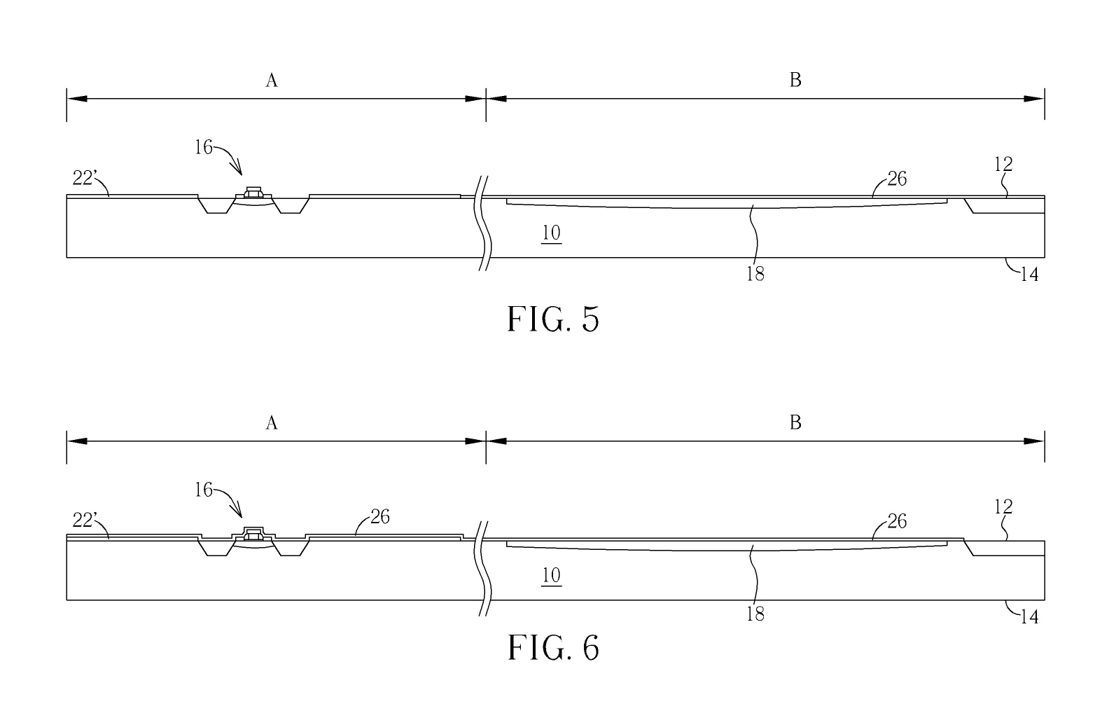

As shown in FIG. 5, the interlayer material 26 within the logic region A is removed by taking the sacrificial layer 24 as an etching stop layer through another lithographic process. Later, the sacrificial layer 24 is removed.

According to another preferred embodiment of the present invention, the interlayer material 26 can be SiN, SiC, or SiON. The step of forming the sacrificial layer 24 illustrated in FIG. 2 to FIG. 3 can be omitted. Because SiN, SiC, and SiON are insulating materials, they can cover on the logic region A without deteriorating the operation of the logic device 16. As shown in FIG. 6, the interlayer material 26 can be therefore formed on both of the logic region A and the MEMS region B, and interlayer material 26 in the logic region A does not need to be removed. As a result, the sacrificial layer 24 serving as the etching stop layer is not needed in this embodiment. When the interlayer material 26 is Co, Ni, Pt, Pd, Mo or Al, the interlayer material 26 on the logic region A is removed. When the interlayer material 26 is SiN, SiC, or SiON, the interlayer material 26 on the logic region A is kept.

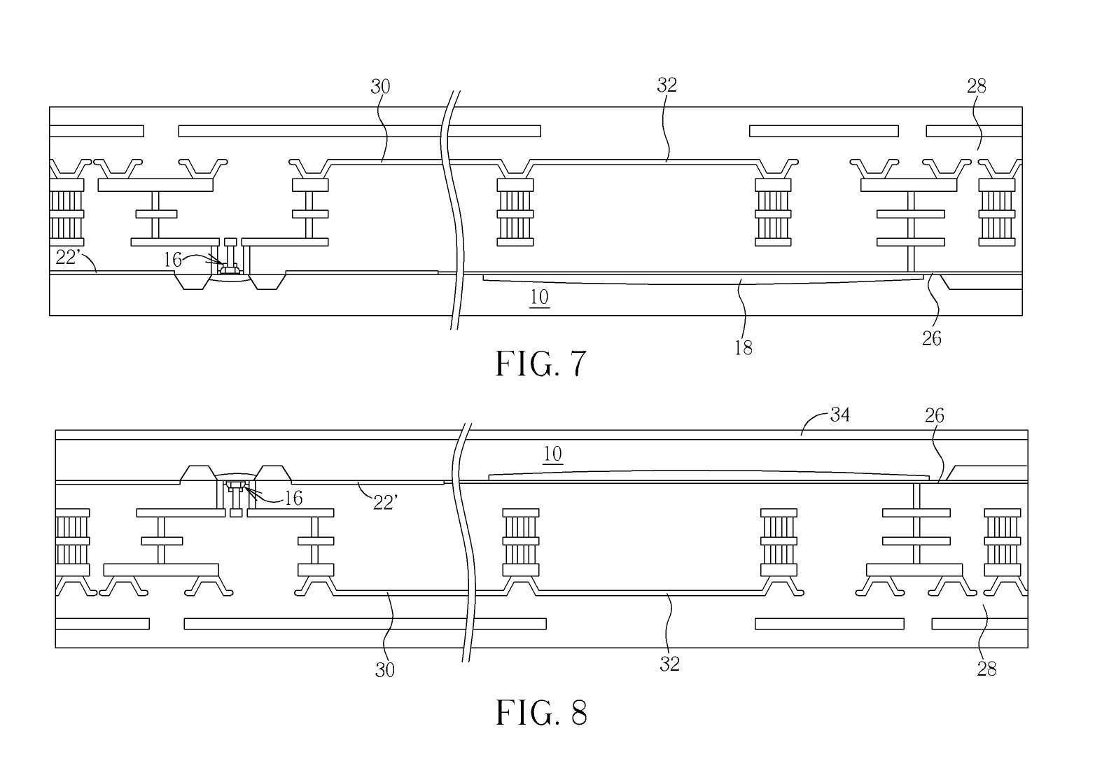

The following process takes the interlayer material 26 is Co, Ni, Pt, Pd, Mo, or Al as example. After the interlayer material 26 is formed, the metal interconnections are formed in the following process. As shown in FIG. 7, a plurality of interlayer dielectric layer 28 is formed on the interlayer material 26 within the MEMS region B, on the logic region A and on the logic device 16. Furthermore, metal interconnections 30 such as contact plugs and metal wires are formed in the interlayer dielectric layers 28 within the logic region A and MEMS region B. The formation of the interlayer dielectric layers 28 and the metal interconnections 30 can be repeated until a completed metal interconnection in the interlayer dielectric layers 28 is formed. At the same time, a MEMS device such as a diaphragm 32 within the MEMS region B can also be formed together with the metal interconnections 30. The diaphragm 32 serves as the vibration film of the MEMS microphone. In addition, the logic device 16 connects electrically to the diaphragm 32 through the metal interconnections 30.

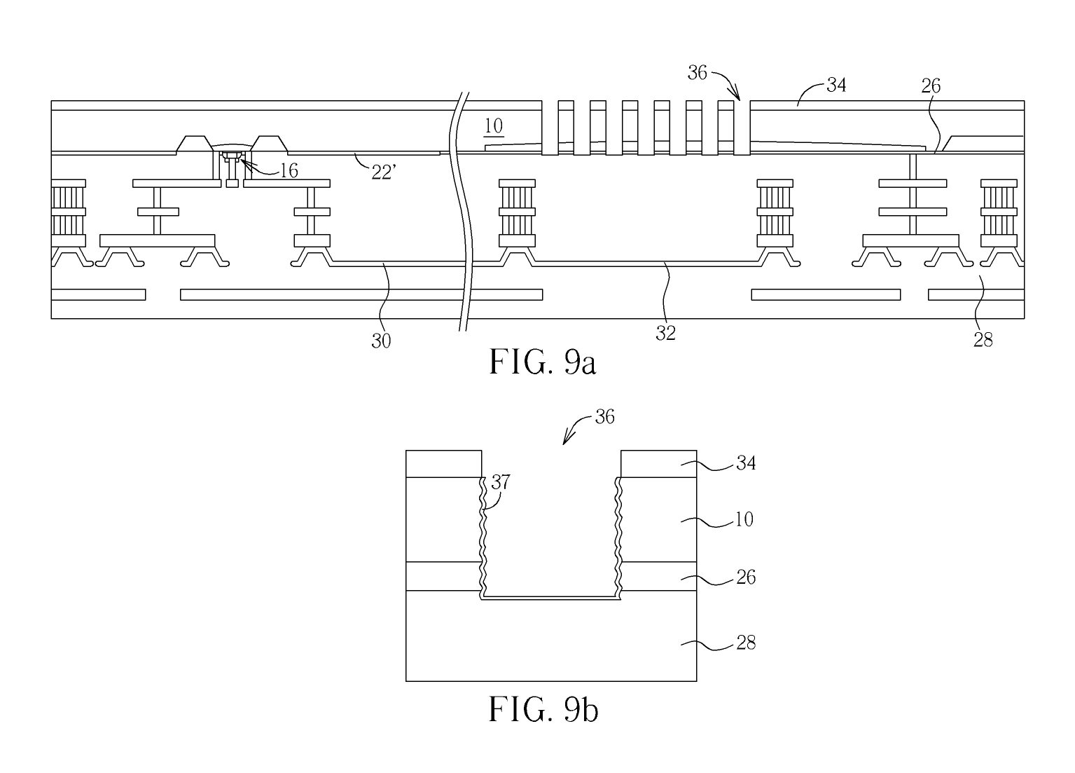

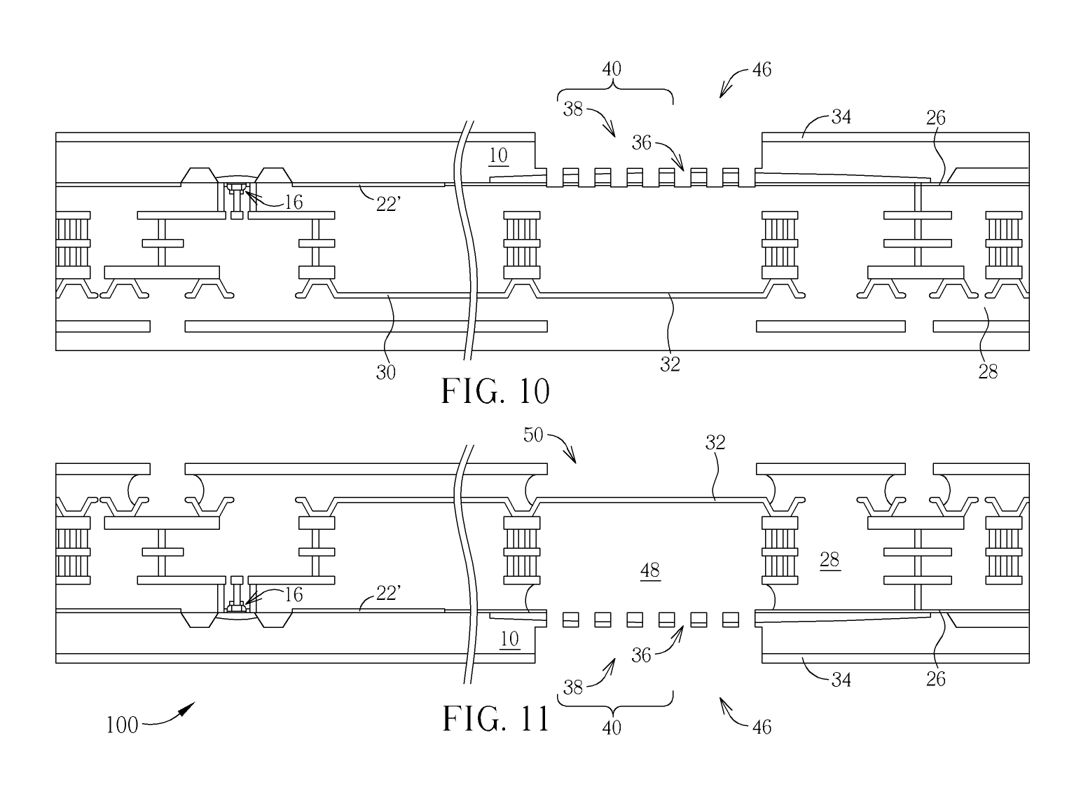

As shown in FIG. 8, the substrate 10 is turned over. Then, a dielectric layer 34 such as silicon oxide is formed on the second surface 14 of the substrate 10. As shown in FIG. 9a, the second surface 14 of the substrate 10 within the MEMS region B is etched to form a plurality of first trenches 36 by a lithographic process, wherein each first trench 36 penetrates the interlayer material 26. FIG. 9b is a magnified localized view of the first trenches 36 shown in FIG. 9a. According to a preferred embodiment of the present invention, SF₆ can be used to etch the substrate 10, and when the substrate 10 is etched by SF₆ to a predetermined depth, SF₆ is turned off and C₄F₈ is induced to form a protective layer 37 on the sidewall of the first trench 36. Later, C₄F₈ can be turned off and SF₆ is turned on to etch the substrate 10 once more. By repeating the above-mentioned process, the first trench 36 can be formed. It is noteworthy that the first surface 12 of the substrate 10 is covered by the interlayer material 26. The interlayer material 26 does not react with any halogen radicals. Therefore, the substrate 10 covered by the interlayer material 26 will not have any undercut after the first trenches 36 are formed. As shown in FIG. 10, after the first trenches 36 are formed, a second trench 38 connecting to each first trench 36 is formed by using the same gas such as SF₆ and C₄F₈. The first trenches 36 and the second trench 38 constitute a vent pattern 40. In addition, the vent pattern 40 can also be formed by forming the second trench 38 before the first trenches 36.

As shown in FIG. 11, part of the interlayer dielectric layer 28 within the MEMS region B is removed. At this point, the diaphragm and the back plate of the MEMS microphone 100 are completed.

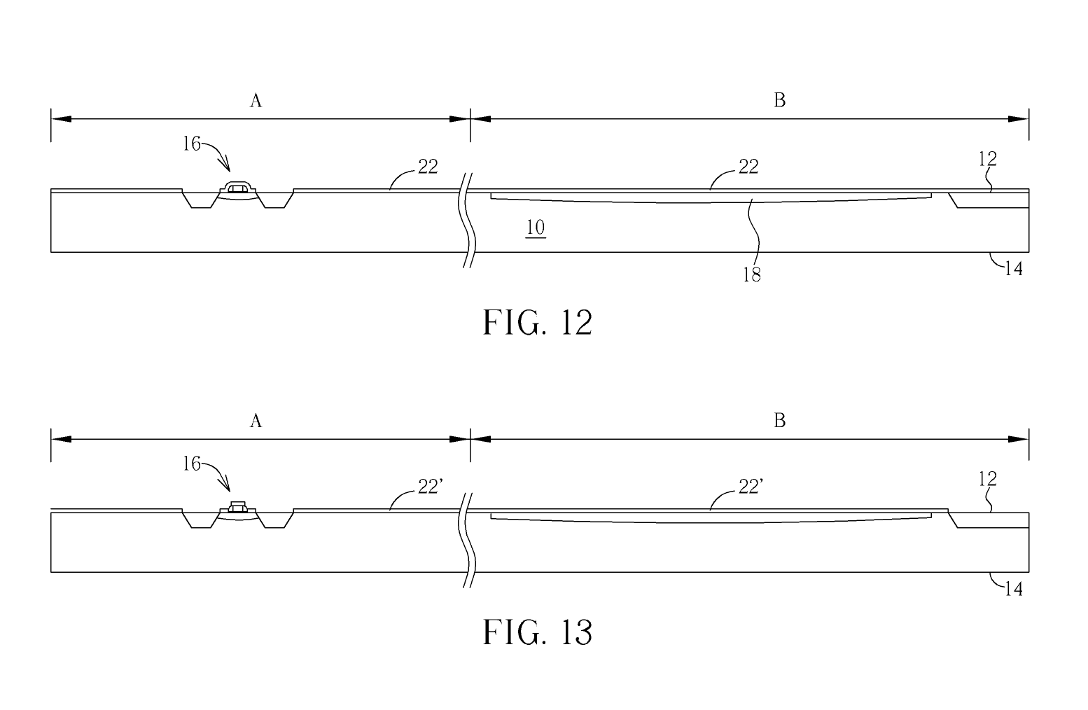

According to another preferred embodiment of the present invention, because the silicided material of Co, Ni, Pt, Pd, Mo, Al and the combination thereof do not react with halogen radicals, they can serve as the interlayer material 26, and the salicide block layer 20 described in FIG. 2 is not needed. Therefore, if the metal layer 22 in FIG. 1 is Co, Ni, Pt, Pd, Mo, Al, or the combination thereof, the fabricating process in FIG. 1 to FIG. 5 can be simplified as follows. Elements with the same function will be given the same reference numeral. As shown in FIG. 12, first, a metal layer 22 is formed on the first surface 12 of the substrate 10 within the logic region A and the MEMS region B and the logic device 16. Then, a salicide process is performed to salicide the logic device 16, the exposed silicon substrate 10 within the MEMS region B, and logic region A, and a silicided layer 22′ is formed on the logic device 16, part of the first surface 12 of the substrate 10 within the logic region A and the MEMS region B. After that, as shown in FIG. 13, the unreacted metal layer 22 within the logic region A and within the MEMS region B is removed. Now, the silicided layer 22′ including CoSi, NiSiPt, PdSi, MoSi or AlSi within the MEMS region B will serve as the interlayer material 26 in the following process. After the interlayer material 26 is formed, the following processes of this embodiment are the same as the processes respectively shown in FIG. 7 to FIG. 11.

According to another preferred embodiment of the present invention, a MEMS device with composite backplate electrode is provided. As shown in FIG. 11, a MEMS device with composite backplate electrode 100, such as a MEMS microphone includes: a composite backplate electrode 46, a diaphragm 32, a chamber 48 disposed between the diaphragm 32 and the composite backplate electrode 46 and a recess 50 disposed aside the diaphragm 32 and opposite the chamber 48. The diaphragm 32 can vibrate after the composite backplate electrode 46 receives signals. The composite backplate electrode 46 includes a first material such as a doped silicon substrate 10, a second material such as the interlayer material 26 partly covering the substrate 10, and a vent pattern 40 disposed in the substrate 10 and the interlayer material 26. The second material, interlayer material 26, can be SiN, SiC, SiON, CoSi, Co, Ni, NiSi, Al, NiSiPt, PdSi, MoSi, AlSi or materials that do not react with halogen radicals.

The diaphragm 32 and the backplate electrode 46 have a voltage between them. The diaphragm 32 vibrates when struck by sound waves, changing the distance between the diaphragm 32 and the backplate electrode 46 and therefore changing the capacitance. Specifically, when the diaphragm 32 and the backplate electrode 46 are closer together, capacitance increases and a charge current occurs. When the diaphragm 32 and the backplate electrode 46 are further apart, capacitance decreases and a discharge current occurs. The current can be an output signal that is stored in a storage device. The MEMS device of the present invention can be applied to cell phones, telephones, notebook computers, cameras, video cameras, bluetooth earphones, MP3 players etc.

The feature of the present invention is that, before the vent pattern is formed, the interlayer material is formed to cover the surface that is an active area of the substrate. It is noteworthy that the interlayer material does not react with halogen radicals. Therefore, the interlayer material will serve as a protective layer to prevent the substrate from having undercut during the formation of the vent pattern.

Those skilled in the art will readily observe that numerous modifications and alterations of the device and method may be made while retaining the teachings of the invention.

What is claimed is:

1. A method of fabricating a MEMS device, comprising:
providing a substrate with a first surface and a second surface, the substrate comprising a logic region and at least one MEMS region, the logic region comprising at least one logic device positioned on the first surface of the substrate;
forming an interlayer material on the first surface of the substrate within the MEMS region; and
patterning the second surface of the substrate within the MEMS region to form a vent pattern in the second surface of the substrate within the MEMS region.

2. The method of fabricating a MEMS device of claim 1, further comprising:
after forming the logic device, and before forming the interlayer material, forming a salicide block layer on the first surface of the substrate within the MEMS region;
forming a first metal layer on the salicide block layer, the logic device and the logic region;
performing a salicide process to the first metal layer on the logic device and on the surface of the substrate;
removing the unreacted first metal layer;
forming a sacrificial layer on the first surface of the substrate within the logic region; and
removing the salicide block layer.

3. The method of fabricating a MEMS device of claim 2, wherein the interlayer material is also formed on the sacrificial layer when the interlayer material is formed on the first surface of the substrate within the MEMS region.

4. The method of fabricating a MEMS device of claim 3, further comprising:
after forming the interlayer material on the first surface of the substrate within the MEMS region, removing the interlayer material on the sacrificial layer; and
removing the sacrificial layer.

5. The method of fabricating a MEMS device of claim 1, wherein the interlayer material is selected from the group consisting of SiN, SiC and SiON.

6. The method of fabricating a MEMS device of claim 1, wherein the interlayer material is selected from the group consisting of, Co, Ni, and Al.

7. The method of fabricating a MEMS device of claim 1, wherein the interlayer material is selected from the group consisting of CoSi, NiSi NiSiPt, PdSi, MoSi and AlSi.

8. The method of fabricating a MEMS device of claim 7, further comprising:
before forming the interlayer material, forming a second metal layer on the MEMS region, the logic region and on the logic device within the logic region, wherein the second metal layer is selected from the group consisting of Co, Ni, Pt, Pd, Mo and Al;
saliciding the second metal layer; and
removing the unreacted second metal layer.

9. The method of fabricating a MEMS device of claim 1, wherein the vent pattern comprises a plurality of first trenches and a second trench connecting to each of the first trenches.

10. The method of fabricating a MEMS device of claim 1, further comprising:
before forming the vent pattern, forming a dielectric layer on the second surface.

11. The method of fabricating a MEMS device of claim 1, further comprising:
before forming the vent pattern, forming an interlayer dielectric layer on the interlayer material within the MEMS region, on the substrate within the logic region and on the logic device, wherein the interlayer dielectric layer comprises a plurality of metal interconnections and a diaphragm, and the logic device connects to the diaphragm electrically through the metal interconnections.

12. The method of fabricating a MEMS device of claim 11, further comprising:
after forming the metal interconnections, removing part of the interlayer dielectric layer within the MEMS region.

13. The method of fabricating a MEMS device of claim 1, wherein the MEMS region comprises a doping region.

14. A MEMS device with composite backplate electrode, comprising:
a composite backplate electrode comprising:
a first material;
a second material formed partly on the first material, wherein the second material does not react with any halogen radical; and
a vent pattern disposed within the first material and the second material.

15. The MEMS device with composite backplate electrode of claim 14, wherein the second material comprises doped silicon.

16. The MEMS device with composite backplate electrode of claim 14, wherein the second material is selected from the group consisting of SiN, SiC and SiON.

17. The MEMS device with composite backplate electrode of claim 14, wherein is selected from the group consisting of Co, Ni, Pt, Pd, Mo, Al, CoSi, NiSiPt, PdSi, MoSi and AlSi.

18. The MEMS device with composite backplate electrode of claim 14, wherein the vent pattern comprises a plurality of first trenches and a second trench connecting to each of the first trenches.

19. The MEMS device with composite backplate electrode of claim 14, further comprising:
a diaphragm;
a chamber disposed between the backplate electrode and the diaphragm; and
a recess disposed aside the diaphragm and opposite the chamber.
